(19) United States
(12) Patent Application Publication
(10) Pub. No.: US 2019/0306973 A1
(43) Pub. Date: Oct. 3, 2019

(54) ELECTRONIC DEVICE

(71) Applicant: FUJITSU LIMITED, Kawasaki-shi (JP)

(72) Inventor: Shunji Baba, Yokohama (JP)

(73) Assignee: FUJITSU LIMITED, Kawasaki-shi (JP)

(21) Appl. No.: 16/285,719

(22) Filed: Feb. 26, 2019

(30) Foreign Application Priority Data
Mar. 28, 2018 (JP) 2018-062354

(51) Int. Cl. H05K 1/02; H05K 1/03; H05K 1/09

(52) U.S. Cl. CPC H05K 1/0283; H05K 1/0281; H05K 1/038; H05K 2201/09263; H05K 2201/0385; H05K 2201/0314; H05K 1/092

(57) ABSTRACT

An electronic device includes a first substrate having bendability, a second substrate configured to include a first electrode and provided over the first substrate, a third substrate configured to include a second electrode and provided over the first substrate with a space from the second substrate, a first electronic component configured to be electrically coupled to the first electrode and provided over the second substrate, a second electronic component configured to be electrically coupled to the second electrode and provided over the third substrate, and a wiring configured to include a plurality of conductive thread-shaped members sewn into the first substrate in an extensible and contractible state so as to be electrically coupled the first electrode to the second electrode.

### CROSS-REFERENCE TO RELATED APPLICATION

This application is based upon and claims the benefit of priority of the prior Japanese Patent Application No. 2018-062354, filed on Mar. 28, 2018, the entire contents of which are incorporated herein by reference.

### FIELD

The embodiments discussed herein are related to an electronic device.

### BACKGROUND

An electronic device has been known in which an electronic component is mounted on a base material having bendability (flexibility) such as, for example, cloth. For example, there has been known a method of electronalizing cloth by using a packaging cloth as a substrate and sewing a conductive area of an electronic module on the packaging cloth to form a circuit board, and sewing the circuit board to clothing cloth with a sewing machine.

In addition, an IC tag has been known, which includes an inlet having a transmission and reception antenna board and a wireless communication IC chip mounted on the surface of the transmission and reception antenna board along with a substrate which is formed of a woven fabric fixed on at least one surface among the front and rear surfaces of the inlet.

In addition, a wearable device has been known, which includes a power generation device, a power storage device, an arithmetic device, a storage device, and a communication device, these devices are configured, either alone or in combination, with a modulated unit block, and the unit block is connected to a flexible circuit board.

Related techniques are disclosed in, for example, Japanese Laid-open Patent Publication Nos. 2014-527278 and 2007-018487, and International Publication Pamphlet No. WO 2016/080182.

### SUMMARY

According to an aspect of the embodiments, an electronic device includes a first substrate having bendability, a second substrate configured to include a first electrode and provided over the first substrate, a third substrate configured to include a second electrode and provided over the first substrate with a space from the second substrate, a first electronic component configured to be electrically coupled to the first electrode and provided over the second substrate, a second electronic component configured to be electrically coupled to the second electrode and provided over the third substrate, and a wiring configured to include a plurality of conductive thread-shaped members sewn into the first substrate in an extensible and contractible state so as to be electrically coupled the first electrode to the second electrode.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a plan view illustrating an example of a configuration of an electronic device according to a first embodiment of the present disclosure;

FIG. 1B is a cross-sectional view taken along line 1B-1B in FIG. 1A;

FIG. 2A is a view illustrating an example of constituent materials of a wiring and an electrode formed on a modular substrate according to an embodiment of the present disclosure;

FIG. 2B is a view illustrating a state where the wiring and the electrode formed on the modular substrate according to the embodiment of the present disclosure are extended;

FIG. 3A is a cross-sectional view illustrating an example of a method of sewing a conductive thread-shaped member according to an embodiment of the present disclosure on a base substrate in an extensible and contractible state;

FIG. 3B is a view illustrating a state where the base substrate according to the embodiment of the present disclosure is extended in the X direction;

FIG. 4A is a plan view illustrating an example of a configuration of an electronic device according to a second embodiment of the present disclosure;

FIG. 4B is a cross-sectional view taken along line 4B-4B in FIG. 4A; and

FIG. 5 is a perspective view illustrating an example of a configuration of a wiring according to a third embodiment of the present disclosure.

### DESCRIPTION OF EMBODIMENTS

A wearable electronic device has been known, in which an electronic component is mounted on a substrate formed of a material having bendability (flexibility) such as, for example, cloth.

For example, in a case where a plurality of electronic components are mounted on a cloth substrate, a configuration is conceivable in which the plurality of electronic components are mounted on a single plastic substrate having a film shape and the electrical connection between the plurality of electronic components is realized by a wiring formed on the plastic substrate. However, in a case where the above configuration is applied to a wearable electronic device, the plastic substrate has no elasticity, so that the sense of wearing deteriorates when the plastic substrate is disposed on a portion in which the cloth substrate bends or is extended and contracted such as, for example, a joint portion.

Hereinafter, in a configuration in which a plurality of electronic components are mounted on a substrate formed of a material having bendability (flexibility), an exemplary embodiment of a technology capable of enhancing adaptability to the bending of the substrate will be described with reference to the drawings. In addition, in the respective drawings, the same or equivalent constituent elements and portions will be denoted by the same reference numerals, and a redundant description thereof will be appropriately omitted.

### First Embodiment

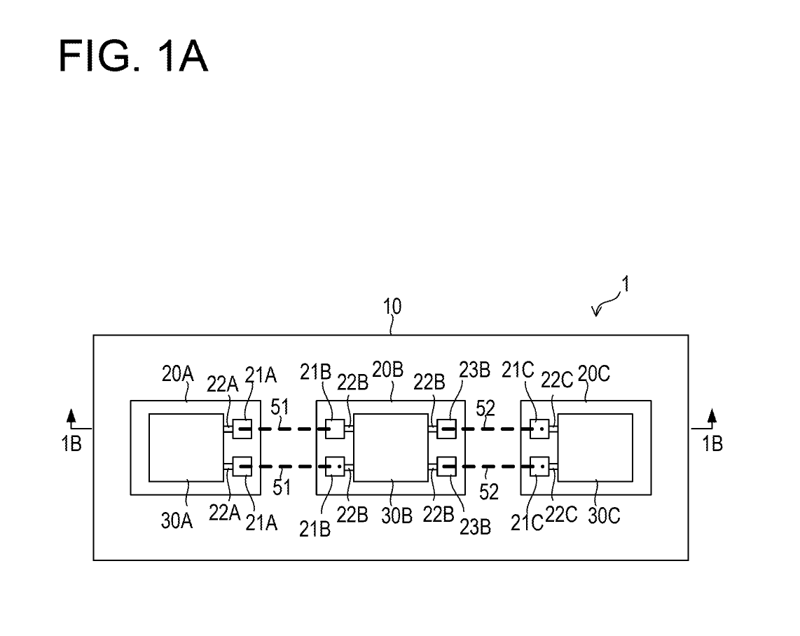

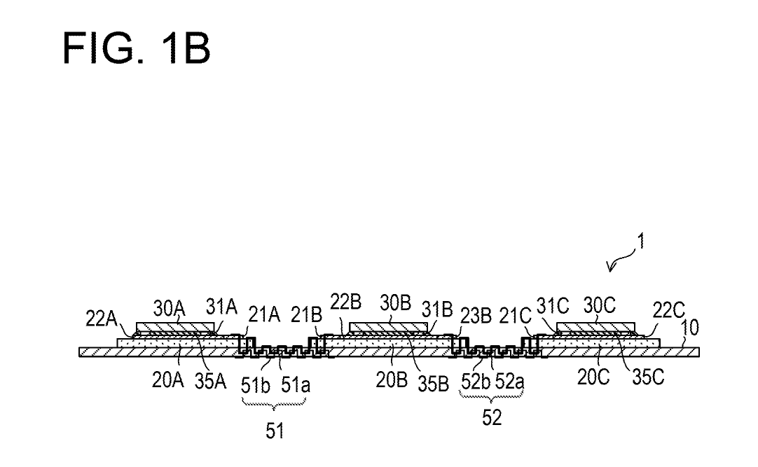

FIG. 1A is a plan view illustrating an example of a configuration of an electronic device 1 according to a first embodiment of the present disclosure. FIG. 1B is a cross-sectional view taken along line 1B-1B in FIG. 1A.

The electronic device 1 includes a base substrate 10 having bendability (flexibility). The base substrate 10 may have elasticity in addition to flexibility. A material of the base substrate 10 may be, for example, cloth. In addition, rubber may also be used as the material of the base substrate 10. In addition, in the present specification, “having elasticity” means that a member is extended and deformed when a tensile force is applied to the member, but returns to the original shape thereof when the external force is removed.

The electronic device 1 includes a plurality of modular substrates 20A, 20B, and 20C which are arranged on the base substrate 10 so as to be spaced apart from each other. Each of the plurality of modular substrates 20A, 20B, and 20C has bendability (flexibility). For example, each of the plurality of modular substrates 20A, 20B, and 20C may be a plastic substrate having a film shape. In addition, at least one of the plurality of modular substrates 20A, 20B, and 20C may have elasticity in addition to bendability (flexibility). Since at least one of the plurality of modular substrates 20A, 20B, and 20C has elasticity, the corresponding modular substrate is extensible and contractible so as to suit to the bending or the extension and contraction of the base substrate 10. For example, at least one of the plurality of modular substrates 20A, 20B, and 20C may be a rubber substrate.

Electrodes 21A and wirings 22A connected to the electrodes 21A are provided on the surface of the modular substrate 20A. Electrodes 21B and 23B and wirings 22B connected to the electrodes 21B and 23B are provided on the surface of the modular substrate 20B. Electrodes 21C and wirings 22C connected to the electrodes 21C are provided on the surface of the modular substrate 20C.

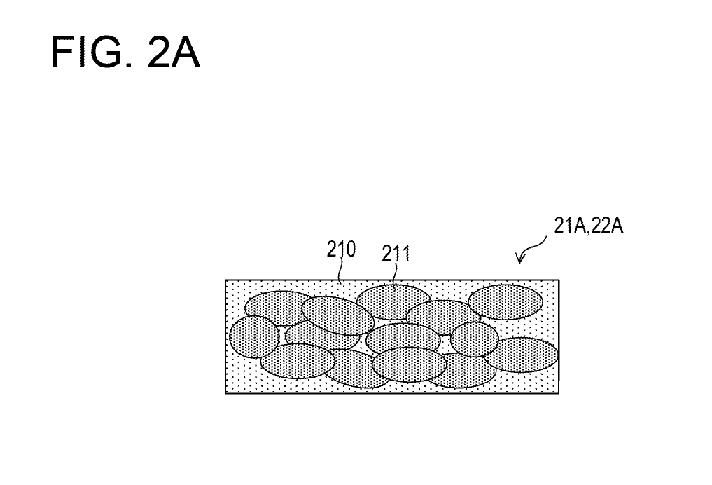

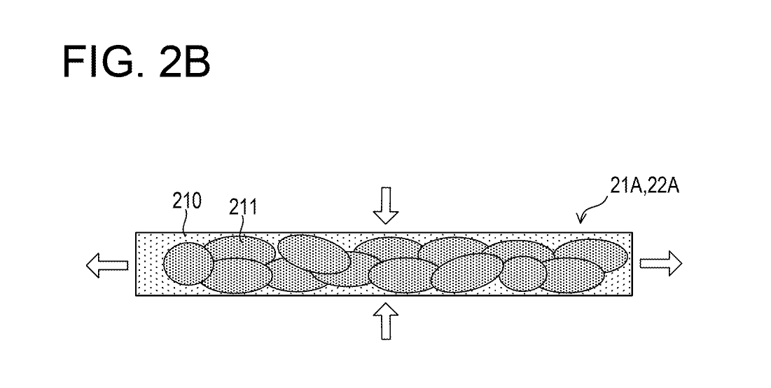

In a case where the modular substrate 20A is a rubber substrate having bendability (flexibility) and elasticity, the electrodes 21A and the wirings 22A may be formed of conductive rubber in which conductive particles 211 are dispersed in a binder 210 which is formed of a rubber-based material having elasticity, as illustrated in FIG. 2A. Since the binder 210 is formed of a rubber-based material, the electrodes 21A and the wirings 22A are extensible and contractible so as to suit to the extension and contraction of the modular substrate 20A. FIG. 2B is a view illustrating a state where the electrodes 21A and the wirings 22A are extended in the horizontal direction in the drawing. When the binder 210 formed of a rubber-based material is extended in the horizontal direction in the drawing, a compressive force acts in the vertical direction in the drawing and the contact between the conductive particles 211 is maintained. Thus, even when the electrodes 21A and the wirings 22A are extended and contracted so as to suit to the extension and contraction of the modular substrate 20A, the conductivity of the electrodes 21A and the wirings 22A is maintained. Even when the modular substrates 20B and 20C are rubber substrates, the electrodes 21B, 23B, and 21C and the wirings 22B and 22C may be formed respectively using a conductive rubber in which conductive particles are dispersed in a binder formed of a rubber-based material.

The electronic device 1 includes an electronic component 30A mounted on the modular substrate 20A, an electronic component 30B mounted on the modular substrate 20B, and an electronic component 30C mounted on the modular substrate 20C.

A terminal 31A of the electronic component 30A is bonded to the wiring 22A of the modular substrate 20A by a conductive bonding member 35A such as, for example, a solder and Ag paste. That is, the terminal 31A of the electronic component 30A is electrically connected to the electrode 21A via the wiring 22A.

Similarly, a terminal 31B of the electronic component 30B is bonded to the wiring 22B of the modular substrate 20B by a conductive bonding member 35B such as, for example, a solder and Ag paste. That is, the terminal 31B of the electronic component 30B is electrically connected to the electrodes 21B and 23B via the wiring 22B.

Similarly, a terminal 31C of the electronic component 30C is bonded to the wiring 22C of the modular substrate 20C by a conductive bonding member 35C such as, for example, a solder and Ag paste. That is, the terminal 31C of the electronic component 30C is electrically connected to the electrode 21C via the wiring 22C.

The electronic component 30A may include, for example, a power generation element such as, for example, a solar cell that generates electric power. For example, the electronic component 30B may include a power storage element such as, for example, a capacitor that accumulates the electric power generated by the electronic component 30A including the power generation element. For example, the electronic component 30C may include a functional component which exerts predetermined functions of a sensor and a control device, for example, which are operated with the electric power generated by the electronic component 30A including the power generation element or the electric power stored in the electronic component 30B including the power storage element. In addition, the functions of the electronic components 30A, 30B, and 30C are not limited to those described above.

In the electronic device 1, for the electrical connection between the electronic component 30A and the electronic component 30B, a wiring 51 including a plurality of conductive thread-shaped members 51a and 51b is used. Similarly, for the electrical connection between the electronic component 30B and the electronic component 30C, a wiring 52 including a plurality of conductive thread-shaped members 52a and 52b is used. As the conductive thread-shaped members 51a, 51b, 52a, and 52b, for example, one in which a conductive metal or graphite is uniformly dispersed in synthetic fibers or metallic fibers which are obtained by fiberizing a metal may be used. In addition, as the conductive thread-shaped members 51a, 51b, 52a, and 52b, for example, one in which the surface of organics fibers is coated with a metal or one in which the surface of organic fibers is coated with a resin containing a conductive material may be used.

The conductive thread-shaped members 51a and 51b are sewn on the base substrate 10 in an extensible and contractible state, respectively. One end of the conductive thread-shaped member 51a is in contact with the electrode 21A of the modular substrate 20A and the other end is in contact with the electrode 21B of the modular substrate 20B. Therefore, the electrode 21A of the modular substrate 20A and the electrode 21B of the modular substrate 20B are electrically connected to each other by the wiring 51 including the conductive thread-shaped members 51a and 51b, and as a result, the electronic component 30A and the electronic component 30B are electrically connected to each other.

Similarly, the conductive thread-shaped members 52a and 52b are sewn on the base substrate 10 in an extensible and contractible state, respectively. One end of the conductive thread-shaped member 52a is in contact with the electrode 23B of the modular substrate 20B and the other end is in contact with the electrode 21C of the modular substrate 20C. Therefore, the electrode 23B of the modular substrate 20B and the electrode 21C of the modular substrate 20C are electrically connected to each other by the wiring 52 including the conductive thread-shaped members 52a and 52b, and as a result, the electronic component 30B and the electronic component 30C are electrically connected to each other.

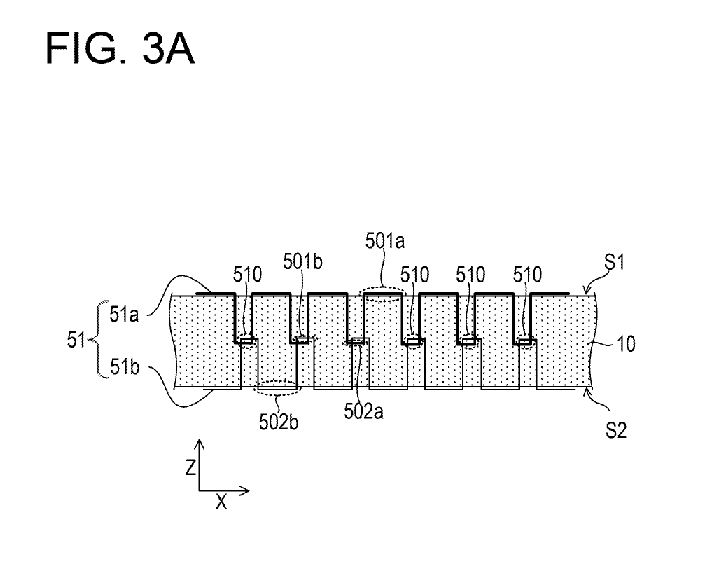

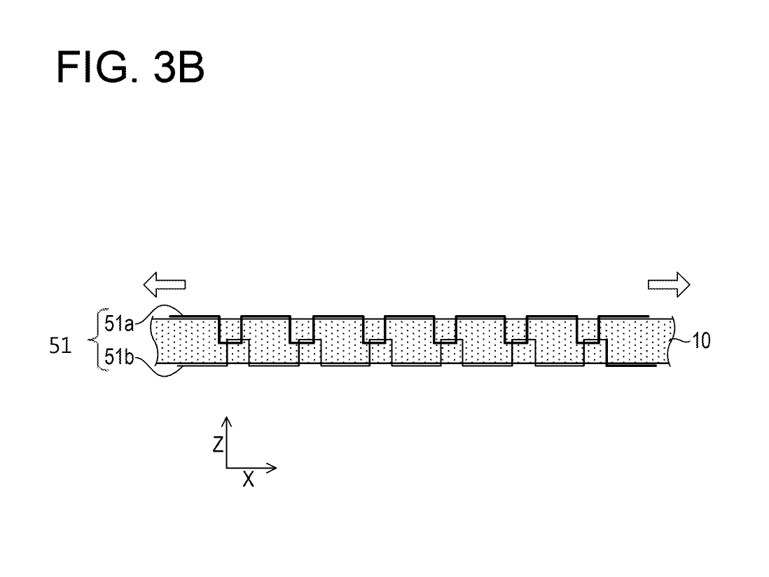

FIG. 3A is a cross-sectional view illustrating an example of a method of sewing the conductive thread-shaped members 51a and 51b on the base substrate 10 in an extensible and contractible state.

Here, the extension direction of the wiring 51 is defined as the X direction, and the direction which is the thickness direction of the base substrate 10 and is orthogonal to the X direction is defined as the Z direction. The conductive thread-shaped member 51a meanders in a plane (X-Z plane) which intersects with a first surface S1 which is a main surface of the base substrate 10 and a second surface S2 which is opposite to the first surface S1 so as to form a plurality of folded portions 501a and 502a. Similarly, the conductive thread-shaped member 51b meanders in a plane (X-Z plane) which intersects with the first surface S1 and the second surface S2 of the base substrate 10 so as to form a plurality of folded portions 501b and 502b. Each folded portion 501b of the conductive thread-shaped member 51b is interlaced with a corresponding one of the folded portions 502a on one side of the conductive thread-shaped member 51a. That is, the respective folded portions 502a and 501b are formed with a fastening portion 510 in which the conductive thread-shaped members 51a and 51b are interlaced with each other. In the present embodiment, the conductive thread-shaped members 51a and 51b have conductivity on at least the surface thereof, respectively, and are electrically connected to each other at each fastening portion 510. That is, the single wiring 51 is formed by the two conductive thread-shaped members 51a and 51b.

FIG. 3B is a view illustrating a state where the base substrate 10 is extended in the X direction. When the base substrate 10 is extended in the X direction and the base substrate 10 is deformed, the conductive thread-shaped members 51a and 51b are deformed so as to suit to the deformation of the base substrate 10. Even when the conductive thread-shaped members 51a and 51b have no elasticity, by sewing the conductive thread-shaped members 51a and 51b into the base substrate 10 so as to meander, the wiring 51 is extensible and contractible so as to suit to the bending or the extension and contraction of the base substrate 10. In addition, this is also equally applied to the conductive thread-like members 52a and 52b constituting the wiring 52.

As described above, in the electronic device 1 according to the embodiment of the present disclosure, the plurality of electronic components 30A, 30B, and 30C are respectively mounted on the modular substrates 20A, 20B, and 20C which are arranged on the base substrate 10 so as to be spaced apart from each other. In addition, for the electrical connection between the electronic component 30A and the electronic component 30B, the wiring 51 which includes the conductive thread-shaped members 51a and 51b sewn on the base substrate 10 in an extensible and contractible state is used. Similarly, for the electrical connection between the electronic component 30B and the electronic component 30C, the wiring 52 which includes the conductive thread-shaped members 52a and 52b sewn on the base substrate 10 in an extensible and contractible state is used.

By separately arranging the plurality of electronic components 30A to 30C on the base substrate 10 and making the wirings 51 and 52 which electrically interconnect the electronic components be extensible and contractible, it is possible to reduce the size of each module and to enhance adaptability to the bending and the extension and contraction of the substrate 10. For example, when the electronic device 1 is used for a wearable electronic device, it is possible to improve the sense of wearing.

In addition, since at least one of the modular substrates 20A to 20C includes a material having bendability (flexibility) and elasticity such as, for example, rubber, it is possible to further enhance adaptability to the bending and the extension and contraction of the base substrate 10. Since the modular substrates 20A to 20C include a material having bendability (flexibility) and elasticity such as, for example, rubber, it is possible to prolong the lifespan of a needle which is used for the sewing of the conductive thread-shaped members 51a, 51b, 52a, and 52b, as compared with a case where the modular substrates 20A, 20B, and 20C are formed of a plastic substrate. In addition, it is possible to increase the resistance of the modular substrates 20A, 20B, and 20C to the sewing of the conductive thread-shaped members 51a, 51b, 52a, and 52b, as compared to a case where the modular substrates 20A, 20B, and 20C are formed of a plastic substrate.

In addition, according to the electronic device 1 of the present embodiment, even if disconnection occurs in one of the two conductive thread-shaped members 51a and 51b, it is possible to maintain power transmission or signal transmission in the wiring 51. Similarly, even if disconnection occurs in the one of two conductive thread-shaped members 52a and 52b, it is possible to maintain power transmission or signal transmission in the wiring 52.

### Second Embodiment

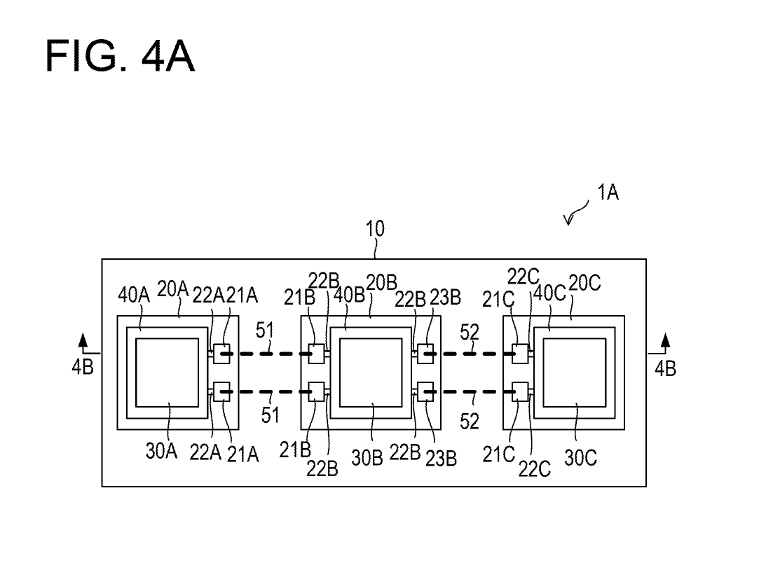

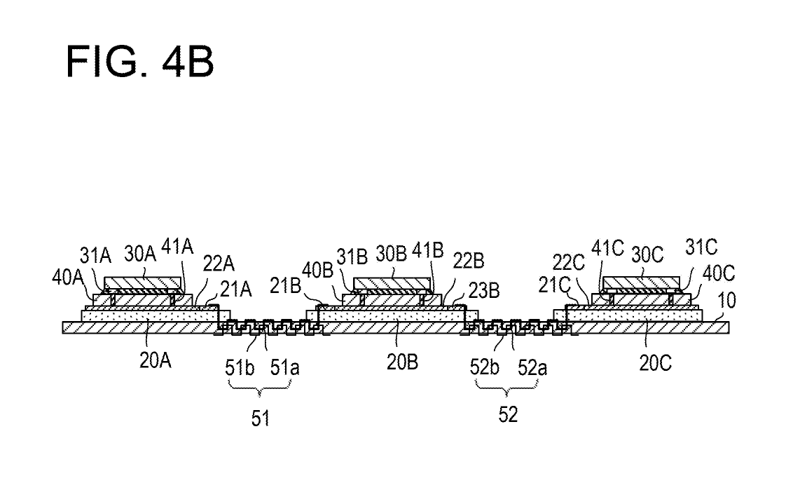

FIG. 4A is a plan view illustrating an example of a configuration of an electronic device 1A according to a second embodiment of the present disclosure. FIG. 4B is a cross-sectional view taken along line 4B-4B in FIG. 4A.

The electronic device 1A according to the second embodiment differs from the electronic device 1 according to the above-described first embodiment in that it includes relay substrates 40A, 40B, and 40C. The relay substrate 40A is provided between the electronic component 30A and the modular substrate 20A. The relay substrate 40B is provided between the electronic component 30B and the modular substrate 20B, and the relay substrate 40C is provided between the electronic component 30C and the modular substrate 20C.

In a typical example of the electronic device 1A, the modular substrates 20A, 20B, and 20C are rubber substrates having bendability (flexibility), and the relay substrates 40A, 40B, and 40c are film-shaped plastic substrates having bendability (flexibility). The sizes of the relay substrates 40A, 40B, and 40C are less than the sizes of the modular substrates 20A, 20B, and 20C, respectively.

The relay substrates 40A, 40B, and 40C include through-electrodes 41A, 41B and 41C, respectively. The terminal 31A of the electronic component 30A is electrically connected to the wiring 22A and the electrode 21A of the modular substrate 20A via the through-electrode 41A. The terminal 31B of the electronic component 30B is electrically connected to the wiring 22B and the electrodes 21B and 23B of the modular substrate 20B via the through-electrode 41B. The terminal 31C of the electronic component 30C is electrically connected to the wiring 22C and the electrode 21C of the modular substrate 20C via the through-electrode 41C.

With the electronic device 1A according to the second embodiment of the present disclosure, similarly to the electronic device 1 according to the first embodiment, it is possible to enhance adaptability to the bending and the extension and contraction of the base substrate 10. In addition, even when it is difficult to directly bond the electronic components 30A to 30C and the modular substrates 20A to 20C, the electrical connection between the electronic components 30A to 30C and the modular substrates 20A to 20C is possible through the use of the relay substrates 40A to 40C. In addition, in a case where the relay substrates 40A to 40C have no elasticity, adaptability to the bending and the extension and contraction of the base substrate 10 may be enhanced by configuring the modular substrates 20A to 20C with rubber substrates having elasticity and minimizing the area of the relay substrates 40A to 40C.

In addition, the present embodiment exemplifies a configuration in which the relay substrates 40A, 40B, and 40C are provided between the electronic components 30A, 30B, and 30C and the modular substrates 20A, 20B, and 20C, respectively, but is not limited thereto. A relay substrate may be provided in at least one of positions between the electronic component 30A and the modular substrate 20A, between the electronic component 30B and the modular substrate 20B, and between the electronic component 30C and the modular substrate 20C.

### Third Embodiment

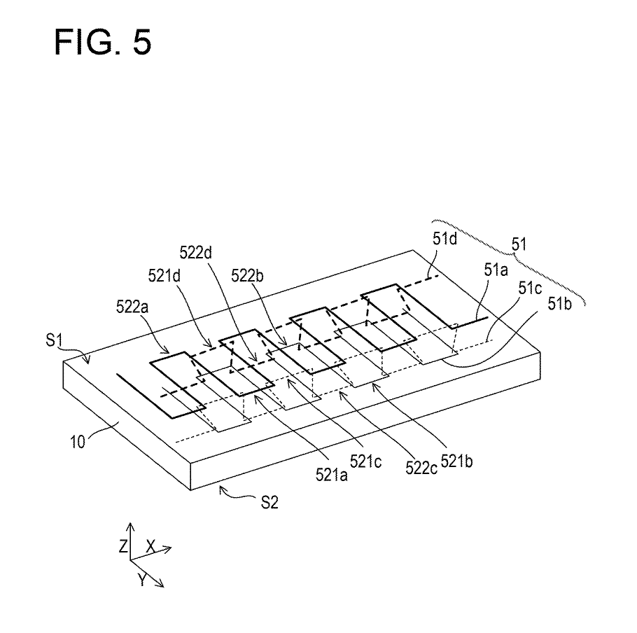

FIG. 5 is a perspective view illustrating an example of a configuration of the wiring 51 according to a third embodiment of the present disclosure. The wiring 51 according to the third embodiment includes four conductive thread-shaped members 51a, 51b, 51c, and 51d. In addition, in FIG. 5, the conductive thread-shaped members 51c and 51d are drawn by broken lines from the viewpoint of distinction of a plurality of conductive thread-shaped members. In addition, the extension direction of the wiring 51 is defined as the X direction, the direction which is the thickness direction of the base substrate 10 and is orthogonal to the X direction is defined as the Z direction, and the direction which is orthogonal to both the X direction and the Z direction is defined as the Y direction.

The conductive thread-shaped member 51a is provided on the side of the first surface S1 of the base substrate 10, and meanders in a plane which is parallel to the first surface S1 of the base substrate 10 so as to form a plurality of folded portions 521a and 522a.

The conductive thread-shaped member 51b is provided on the side of the second surface S2 of the base substrate 10, and meanders in a plane which is parallel to the second surface S2 of the base substrate 10 so as to form a plurality of folded portions 521b and 522b.

The conductive thread-shaped member 51c meanders in a plane (X-Z plane) which intersects with the first surface S1 and the second surface S2 of the base substrate 10 so as to form a plurality of folded portions 521c and 522c. Each folded portion 521c of the conductive thread-shaped member 51c is interlaced with a corresponding one of the folded portions 521a of the conductive thread-shaped member 51a, and each folded portion 522c of the conductive thread-shaped member 51c is interlaced with a corresponding one of the folded portions 521b of the conductive thread-shaped member 51b.

The conductive thread-shaped member 51d meanders in a plane (X-Z plane) which intersects with the first surface S1 and the second surface S2 of the base substrate 10 so as to form a plurality of folded portions 521d and 522d. Each folded portion 521d of the conductive thread-shaped member 51d is interlaced with a corresponding one of the folded portions 522a of the conductive thread-shaped member 51a, and each folded portion 522d of the conductive thread-shaped member 51d is interlaced with a corresponding one of the folded portions 522b of the conductive thread-shaped member 51b.

By sewing the four conductive thread-shaped members 51a, 51b, 51c, and 51d on the base substrate 10 as described above, the wiring 51 may have high elasticity not only in the X direction but also in the Y direction.

In addition, by increasing the number of conductive thread-shaped members constituting the wiring 51, it is possible to further reduce the resistance value of the wiring 51. In addition, it is possible to enhance the redundancy of the wiring 51 and to improve the reliability thereof. In addition, similarly to the wiring 51, the wiring 52 may be formed of four conductive thread-shaped members.

In addition, the electronic devices 1 and 1A are examples of the electronic device of the present disclosure. The base substrate 10 is an example of a first substrate of the present disclosure. The modular substrate 20A is an example of a second substrate of the present disclosure. The modular substrate 20B is an example of a third substrate of the present disclosure. The electronic component 30A is an example of a first electronic component of the present disclosure. The electronic component 30B is an example of a second electronic component of the present disclosure. The relay substrates 40A and 40B are examples of a fourth substrate of the present disclosure. The conductive thread-shaped members 51a, 51b, 51c, and 51d are examples of a plurality of conductive thread-shaped members of the present disclosure. The wiring 51 is an example of a wiring of the present disclosure.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a first substrate having bendability;
a second substrate configured to include a first electrode and provided over the first substrate;
a third substrate configured to include a second electrode and provided over the first substrate with a space from the second substrate;
a first electronic component configured to be electrically coupled to the first electrode and provided over the second substrate;
a second electronic component configured to be electrically coupled to the second electrode and provided over the third substrate; and
a wiring configured to include a plurality of conductive thread-shaped members sewn into the first substrate in an extensible and contractible state so as to be electrically coupled the first electrode to the second electrode.

2. The electronic device according to claim 1,
wherein the first substrate has elasticity.

3. The electronic device according to claim 1,
wherein the first substrate is configured to include cloth.

4. The electronic device according to claim 1,
wherein at least one of the second substrate and the third substrate has elasticity.

5. The electronic device according to claim 1,
wherein at least one of the second substrate and the third substrate is configured to include rubber.

6. The electronic device according to claim 5,
wherein at least of the first electrode of the second substrate including rubber and the second electrode of the third substrate including rubber is configured to be formed of conductive rubber in which conductive particles are dispersed in a binder including rubber.

7. The electronic device according to claim 1, further comprising:
a fourth substrate provided in at least one of positions between the second substrate and the first electronic component and between the third substrate and the second electronic component.

8. The electronic device according to claim 1,
wherein the first electronic component is configured to include a power generation element that generates electric power, and
wherein the second electronic component is configured to include a power storage element that accumulates the electric power generated by the power generation element.

9. The electronic device according to claim 1,
wherein the wiring is configured to include a plurality of conductive thread-shaped members sewn in a meandering manner into the first substrate so as to form a plurality of fastening portions that are interlaced with each other.

10. The electronic device according to claim 9,
wherein the plurality of conductive thread-shaped members are electrically coupled to each other at the fastening portions.

11. The electronic device according to claim 1,
wherein the wiring is configured to include:
a first conductive thread-shaped member configured to meander in a plane intersecting with a first surface of the first substrate so as to form a plurality of folded portions, and
a second conductive thread-shaped member configured to meander in a plane intersecting with the first surface of the first substrate so as to form a plurality of folded portions, each of the plurality of folded portions of the second conductive thread-shaped member being interlaced with a corresponding one of the plurality of folded portions on a side of the first conductive thread-shaped member.

12. The electronic device according to claim 1,
wherein the wiring is configured to include:
a first conductive thread-shaped member configured to be provided into a first surface of the first substrate and configured to meander in a plane parallel to the first surface of the first substrate so as to form a plurality of folded portions,
a second conductive thread-shaped member configured to be provided into a second surface of the first substrate opposite to the first surface and configured to meander in a plane parallel to the second surface of the first substrate so as to form a plurality of folded portions,
a third conductive thread-shaped member configured to meander in a plane intersecting with the first surface and the second surface so as to form a plurality of folded portions, each folded portion of the third conductive thread-shaped member being interlaced with a corresponding one of the plurality of folded portions on a first side of the first conductive thread-shaped member and the second conductive thread-shaped member, and
a fourth conductive thread-shaped member configured to meander in a plane intersecting with the first surface and the second surface so as to form a plurality of folded portions, each folded portion of the fourth conductive thread-shaped member being interlaced with a corresponding one of the plurality of folded portions on a second side of the first conductive thread-shaped member and the second conductive thread-shaped member.

13. The electronic device according to claim 1,
wherein both the second substrate and the third substrate are configured to include rubber.

14. The electronic device according to claim 1, further comprising:
fourth substrates configured to include plastic provided between the second substrate and the first electronic component and between the third substrate and the second electronic component,
wherein both the second substrate and the third substrate are configured to include rubber.
